(19) United States
(12) Patent Application Publication
(10) Pub. No.: US 2008/0134964 A1
(43) Pub. Date: Jun. 12, 2008

(54) System and Method of Forming a Crystal

(75) Inventors: David Harvey, Westford, MA (US); Weidong Huang, Acton, MA (US); Richard L. Wallace, Acton, MA (US); Leo van Glabbeek, Franklin, MA (US); Emanuel M. Sachs, Newton, MA (US)

Correspondence Address: BROMBERG & SUNSTEIN LLP, 125 SUMMER STREET, BOSTON, MA, 02110-1618, US

(73) Assignee: Evergreen Solar, Inc., Marlborough, MA (US)

(21) Appl. No.: 11/741,372

(22) Filed: Apr. 27, 2007

Related U.S. Application Data
(60) Provisional application No. 60/873,177, filed on Dec. 6, 2006.
(60) Provisional application No. 60/922,355, filed on Apr. 6, 2007.

(51) Int. Cl. C30B 15/34

(52) U.S. Cl. 117/211; 117/26

(57) ABSTRACT

A system for producing a crystal formed from a material with impurities has a crucible for containing the material. The crucible has, among other things, a crystal region for forming the crystal, an introduction region for receiving the material, and a removal region for removing a portion of the material. The crucible is configured to produce a generally one directional flow of the material (in liquid form) from the introduction region toward the removal region. This generally one directional flow causes the removal region to have a higher concentration of impurities than the introduction region.

### PRIORITY

This patent application claims priority from provisional U.S. patent application No. 60/873,177, filed Dec. 6, 2006, entitled, “UTILIZING LOWER PURITY FEEDSTOCK IN SEMICONDUCTOR RIBBON GROWTH,” and naming David Harvey, Emanuel Michael Sachs, Richard Lee Wallace Jr., and Weidong Huang as inventors, the disclosure of which is incorporated herein, in its entirety, by reference.

This patent application also claims priority from provisional U.S. patent application Ser. No. ______, filed Apr. 6, 2007, entitled, “UTILIZING LOWER PURITY FEEDSTOCK IN SEMICONDUCTOR RIBBON GROWTH,” and naming David Harvey, Emanuel Michael Sachs, Richard Lee Wallace Jr., and Weidong Huang as inventors, the disclosure of which is incorporated herein, in its entirety, by reference.

### FIELD OF THE INVENTION

The invention generally relates to crystal growth and, more particularly, the invention relates to systems and methods of facilitating the crystal growth process.

### BACKGROUND OF THE INVENTION

Silicon wafers form the building blocks of a wide variety of semiconductor devices, such as solar cells, integrated circuits, and MEMS devices. These devices often have varying carrier lifetimes, which impacts device performance. For example, a silicon-based solar cell with a higher carrier lifetime may more effectively convert solar energy with a higher efficiency into electric energy than a silicon-based solar cell with a lower carrier lifetime. The carrier lifetime of a device generally is a function of the concentration of impurities in the silicon wafers from which the device was formed. Higher efficiency devices therefore often are formed from silicon wafers having lower impurity concentrations.

The impurity concentration of a silicon wafer, however, generally depends upon the concentration of impurities in the silicon feedstock from which it was formed. Undesirably, silicon feedstock with a lower impurity concentration typically is more expensive than silicon feedstock with a higher impurity concentration. Those in the art therefore often are unable to produce higher efficiency devices without increasing production costs.

### SUMMARY OF THE INVENTION

In accordance with one embodiment of the invention, a system for producing a crystal formed from a material with impurities has a crucible for containing the material. The crucible has, among other things, a crystal region for forming the crystal, an introduction region for receiving the material, and a removal region for removing a portion of the material. The crucible is configured to produce a generally one directional flow of the material (in liquid form) from the introduction region toward the removal region. This generally one directional flow causes the removal region to have a higher concentration of impurities than the introduction region.

Some embodiments of the crucible have a narrowing end portion containing at least a portion of the removal region. Other embodiments of the crucible have an elongated shape with a length dimension and a width dimension. The crystal region may be positioned between the introduction region and the removal region along the long dimension. In addition, the length dimension may be at least three times greater than the width dimension. Moreover, the crucible illustratively is configured to direct the flow of the material generally in one direction toward the removal region in the length direction.

The removal region may employ any of a number of different ways for removing the material. For example, the removal region may have a removal port, which is spaced from the crystal region, for removing a portion of the material. The system thus may have a pressure source for urging material through the removal port, or rely on a gravity feed. To receive the removed material, the system also may have a container coupled to the removal port. Alternatively, or in addition, the system may have a wick traversing the removal region for removing the material.

The crucible may be configured to cause the material to have a generally increasing amount of impurities from the introduction region toward the removal region. For example, the generally one directional flow may cause the removal region to have a higher concentration of impurities than the average of the impurities in the crystal region.

In some embodiments, the crucible is substantially planar and contains the material by surface tension. Moreover, the crucible may be configured to cause substantially no rotational flow of the material in or immediately proximate to the crystal region. It also is anticipated that various embodiments may be used to grow a plurality of crystals. In that case, the crystal region includes a plurality of crystal sub-regions for growing a plurality of crystals.

In accordance with another embodiment of the invention, a method of forming a crystal adds material to an introduction region of a crucible. In a manner similar to the crucible discussed above, this crucible also has a crystal region and a removal region. The method then causes the material to flow in a substantially one directional manner in the direction of the removal region. At least some of the impurities flow with the one directional flow to the removal region. The method also removes a portion of the material from the removal region.

In accordance with another embodiment of the invention, a ribbon pulling system for producing a ribbon crystal formed from silicon having impurities includes a crucible for containing liquid silicon. In a manner to those embodiments discussed above, the crucible has a crystal region for forming the crystal, an introduction region for receiving silicon, and a removal region for removing a portion of the silicon in liquid form. The crucible is configured to produce a generally one directional flow of the silicon (in liquid form) from the introduction region toward the removal region. This generally one directional flow causes the removal region to have a higher concentration of impurities than the introduction region.

In accordance with another embodiment of the invention, a system for producing a ribbon crystal formed from a material having impurities has a crucible for containing the material. This crucible also has a crystal region for forming the crystal, an introduction region for receiving the material, and a removal region for removing a portion of the material. The crucible is configured to cause the substantial majority of material to flow generally directly from the introduction region toward the removal region. This flow causes the removal region to have a higher concentration of impurities than the introduction region.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a silicon ribbon crystal growth furnace that may implement illustrative embodiments of the invention.

FIG. 2 schematically shows a partially cut away view of the crystal growth furnace shown in FIG. 1.

FIG. 3A schematically shows a crucible configured in accordance with illustrative embodiments of the invention.

FIG. 3B schematically shows an embodiment of the crucible containing liquid silicon and growing a plurality of silicon ribbon wafers.

FIG. 4 graphically shows an example of impurity concentrations within the melt material of the crucible.

FIG. 5 schematically shows a cross-sectional view of the crucible as shown in FIG. 3B.

FIG. 6 schematically shows a longitudinal cross-sectional, perspective view of a portion of the crucible shown in FIG. 3A.

FIG. 7A schematically shows a partial cross-section of an outlet port of the crucible, and an apparatus for facilitating melt dumping in accordance with one embodiment of the invention.

FIG. 7B schematically shows a partial cross-section of an outlet port of the crucible, and an apparatus for facilitating melt dumping in accordance with a second embodiment of the invention.

FIG. 7C schematically shows a partial cross-section of an outlet port of the crucible, and an apparatus for facilitating melt dumping in accordance with a third is embodiment of the invention.

FIGS. 7D and 7E schematically show an apparatus for facilitating melt dumping in accordance with a fourth is embodiment of the invention.

FIG. 8 shows a process of melt dumping in accordance with illustrative embodiments of the invention.

FIG. 9 schematically shows a top view of a crucible having a narrowing end portion in accordance with alternative embodiments of the invention.

FIGS. 10A, 10B, and 10C schematically show plan views of three additional alternative embodiments of the crucible.

### DESCRIPTION OF ILLUSTRATIVE EMBODIMENTS

In illustrative embodiments, a crystal growth system has a crucible configured to produce higher quality crystals from lower quality material feedstock. Accordingly, the system should reduce crystal production costs, correspondingly reducing the cost of devices formed from these crystals.

To that end, the crucible has a removal region for selectively removing higher impurity molten material flushed there by a generally one directional flow. More specifically, this flow causes many of the impurities in the material to flow (with the flow of the material) from an upstream region of the crucible to the removal region. Tests using a silicon melt have shown that this flow causes impurities to accumulate at the removal region.

Removal of material from the removal region has the net effect of removing impurities from the crucible, consequently enabling the system to produce crystals with lower impurity concentrations. Details of illustrative embodiments are discussed below.

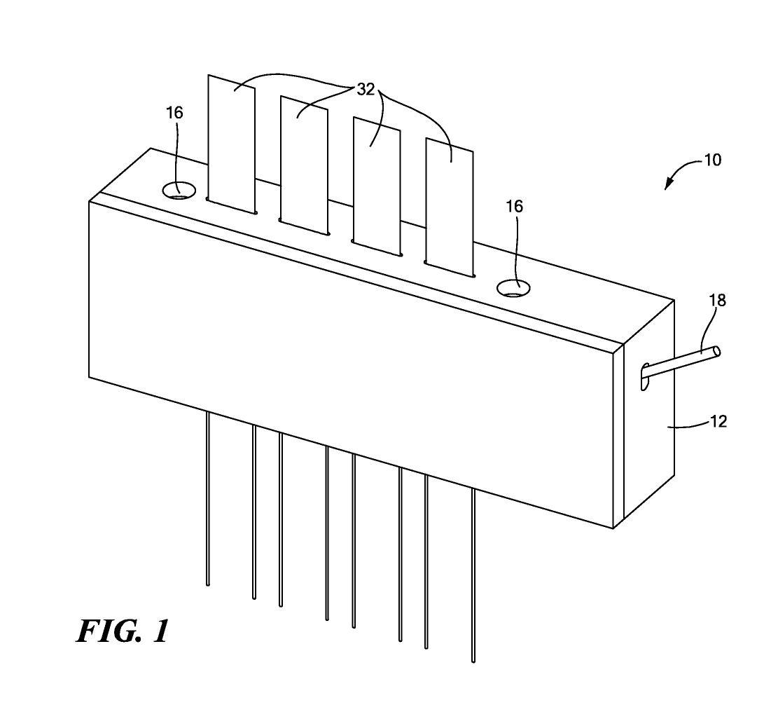

FIG. 1 schematically shows a silicon ribbon crystal growth furnace 10 that may implement illustrative embodiments of the invention. The furnace 10 has, among other things, a housing 12 forming a sealed interior that is substantially free of oxygen (to prevent combustion). Instead of oxygen, the interior has some concentration of another gas, such as argon, or a combination of gasses. The housing interior also contains, among other things, a crucible 14 and other components (some of which are discussed below) for substantially simultaneously growing four silicon ribbon crystals 32. The ribbon crystals 32 may be any of a wide variety of crystal types, such as multi-crystalline, single crystalline, polycrystalline, microcrystalline or semi-crystalline. A feed inlet 18 in the housing 12 provides a means for directing silicon feedstock to the interior crucible 14, while an optional window 16 permits inspection of the interior components.

It should be noted that discussion of silicon ribbon crystals 32 is illustrative and not intended to limit all embodiments of the invention. For example, the crystals may be formed from a material other than silicon, or a combination of silicon and some other material. As another example, illustrative embodiments may form non-ribbon crystals.

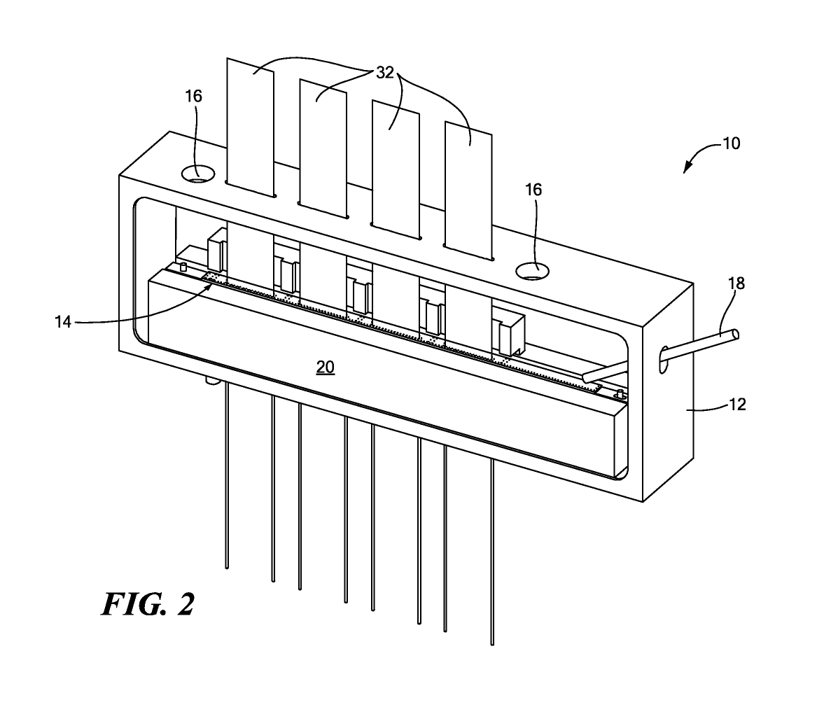

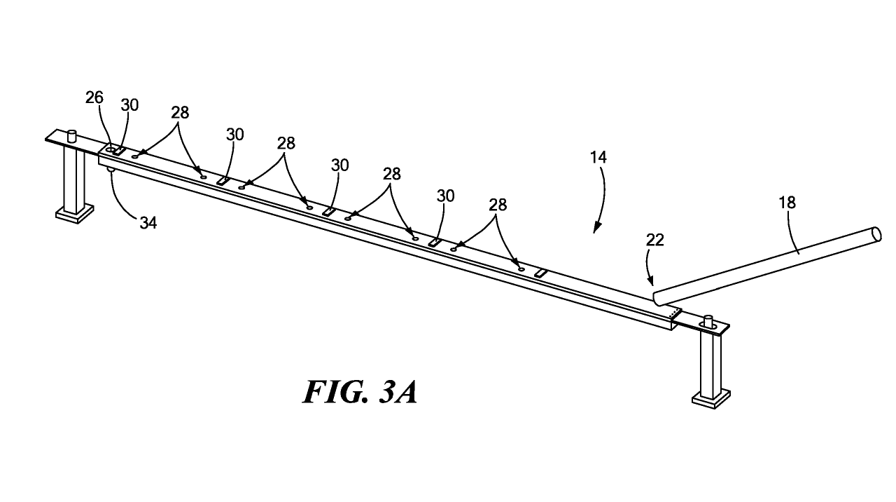

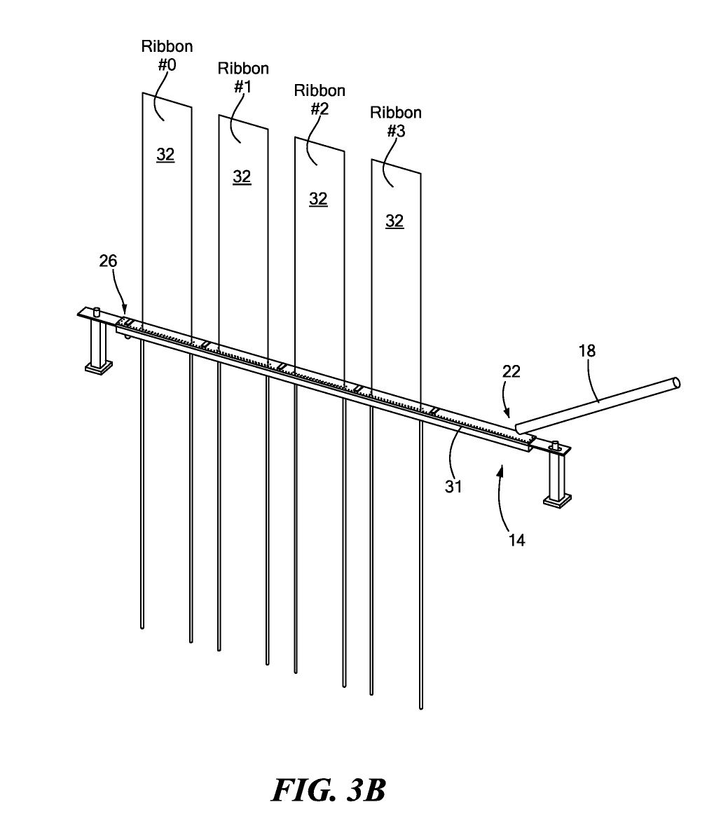

FIG. 2 schematically shows a partially cut away view of the crystal growth furnace 10 shown in FIG. 1. This view shows, among other things, the above noted crucible 14, which is supported on an interior platform 20 within the housing 12 and has a substantially flat top surface. As shown in FIG. 3A, this embodiment of the crucible 14 has an elongated shape with a region for growing silicon ribbon crystals 32 in a side-by-side arrangement along its length.

In illustrative embodiments, the crucible 14 is formed from graphite and resistively heated to a temperature capable of maintaining silicon above its melting point. To improve results, the crucible 14 has a length that is much greater than its width. For example, the length of the crucible 14 may be three or more times greater than its width. Of course, in some embodiments, the crucible 14 is not elongated in this manner. For example, the crucible 14 may have a somewhat square shape, or a nonrectangular shape. For simplicity, all embodiments of the crucible are identified by reference number 14.

The crucible 14 may be considered as having three separate but contiguous regions; namely, 1) an introduction region 22 for receiving silicon feedstock from the housing feed inlet 18, 2) a crystal region 24 for growing four ribbon crystals 32, and 3) a removal region 26 for removing a portion of molten silicon contained by the crucible 14 (i.e., to perform a dumping operation). In the embodiment shown, the removal region 26 has a port 34 for facilitating silicon removal. As discussed in detail below, however, other embodiments do not have such a port 34.

The crystal region 24 may be considered as forming four separate crystal sub-regions that each grow a single ribbon crystal 32. To that end, each crystal sub-region has a pair of string holes 28 for respectively receiving two high temperature strings that ultimately form the edge area of a growing silicon ribbon crystal 32. Moreover, each sub-region also may be considered as being defined by a pair of optional flow control ridges 30. Accordingly, each sub-region has a pair of ridges 30 that forms its boundary, and a pair of string holes 28 for receiving string. As shown in the figures, the middle crystal sub-regions share ridges 30 with adjacent crystal sub-regions. Moreover, in addition to dividing the crystal sub-regions, the ridges 30 also present some degree of fluid resistance to the flow of the molten silicon, thus providing a means for controlling fluid flow along the crucible 14.

In a manner similar to other aspects of the invention, discussion of four crystal sub-regions is but one embodiment. Various aspects of the invention can be applied to crucibles 14 having fewer than four crystal sub-regions (e.g., one, two or three sub-regions), or more than four crystal sub-regions. Accordingly, discussion of one crystal sub-region is for illustrative purposes only and not intended to limit all embodiments. In a similar manner, discussion of plural ribbon crystals 32 is one embodiment. Some embodiments apply to systems growing a single ribbon crystal 32 only.

FIG. 3B schematically shows an embodiment of the crucible 14 with shallow perimeter walls 31. In addition, this figure shows this embodiment of the crucible 14 containing liquid silicon and growing four silicon ribbon crystals 32. As shown, the crystal sub-region closest to the introduction region 22, referred to as a first sub-region, grows “ribbon three,” while a second sub-region grows “ribbon two.” A third sub-region grows “ribbon one,” and a fourth sub-region, which is closest to the removal region 26, grows “ribbon zero.” As known by those skilled in the art, continuous silicon ribbon crystal growth may be carried out by introducing two strings of high temperature material through string holes 28 in the crucible 14. The strings stabilize the edges of the growing ribbon crystal 32 and, as noted above, ultimately form the edge area of a growing silicon ribbon crystal 32.

As shown in FIG. 3B, the molten silicon drawn upwardly integrates with the string and existing frozen ribbon crystal 32 just above the top surface of the molten silicon. It is at this location (referred to as the “interface”) that the solid ribbon crystal 32 typically rejects a portion of the impurities from its crystalline structure. Among other things, such impurities may include iron, carbon, tungsten and iron. The impurities thus are rejected back into the molten silicon, consequently increasing the impurity concentration within the crystal region 24. During this process, each ribbon crystal 32 preferably is drawn from the molten silicon at a very low rate. For example, each ribbon crystal 32 may be pulled from the molten silicon at a rate of about one inch per minute.

In accordance with illustrative embodiments of the invention, the crucible 14 is configured to cause the molten silicon to flow at a very low rate from the introduction region 22 toward the removal region 26. If this flow rate were too high, the growing crystals undesirably may grow in an undesirable manner and thus, be less useful. It is this low flow that causes a portion of the impurities within the molten silicon, including those rejected by the growing crystals, to flow from the crystal region 24 toward the removal region 26.

Several factors contribute to the flow rate of the molten silicon toward the removal region 26. Each of these factors relates to adding or removing silicon to and from the crucible 14. Specifically, a first of these factors simply is the removal of silicon caused by the physical upward movement of the strings through the melt. For example, removal of four ribbons crystals 32 at a rate of 1 inch per minute, where each ribbon crystal 32 has a width of about three inches and a thickness ranging between about 190 microns to about 300 microns, removes about three grams of molten silicon per minute. A second of these factors affecting flow rate is the selective removal/dumping of molten silicon from the removal region 26.

Consequently, to maintain a substantially constant melt height, the system adds new silicon feedstock as a function of the desired melt height in the crucible 14. To that end, among other ways, the system may detect changes in the electrical resistance of the crucible 14, which is a function of the melt it contains. Accordingly, the system may add new silicon feedstock to the crucible 14, as necessary, based upon the resistance of the crucible 14. For example, in some implementations, the melt height may be generally maintained by adding one generally spherical silicon slug having a diameter of about a few millimeters about every one second. See, for example, the following United States patents (the disclosures of which are incorporated herein, in their entireties, by reference) for additional information relating to the addition of silicon feedstock to the crucible 14 and maintenance of a melt height.
U.S. Pat. No. 6,090,199
U.S. Pat. No. 6,200,383, and
U.S. Pat. No. 6,217,649.

The flow rate of the molten silicon within the crucible 14 therefore is caused by this generally continuous/intermittent addition and removal of silicon to and from the crucible 14. It is anticipated that at appropriately low flow rates, the geometry and shape of various embodiments of the crucible 14 should cause the molten silicon to flow toward the removal region 26 by means of a generally one-directional flow. By having this generally one directional flow, the substantial majority of the molten silicon (substantially all molten silicon) flows directly toward the removal region 26.

While flowing in this manner, some of the molten silicon will contact the very thin side of a growing ribbon crystal 32. As noted above, in illustrative embodiments, this thin side of the ribbon crystal 32 may be between about 190 and 300 microns. In some embodiments, the ribbon crystal 32 may have portions as thin as about 60 microns. Consequently, the flow resistance caused by the side of the ribbon crystal 32 should be substantially negligible to the flow of silicon toward the removal region 26. This resistance, however, may cause some very small, negligible, localized flow of the molten silicon in a direction that is not directed toward the removal region 26. It nevertheless is anticipated that the molten silicon should smoothly flow past this point and not cause significant movement of impurities in any direction other than toward the removal region 26. In fact, due to their thin profile, the growing ribbon crystals 32 actually may be considered as functioning like fins to ensure/promote a substantially one directional fluid flow toward the removal region 26.

As noted above, the crucible 14 may have other means for creating resistance to the flow of molten silicon; namely, in the embodiment shown, the plurality of ridges 30 separating the different sub-regions of the crystal region 24. Like the sides of the growing ribbon crystals 32, these ridges 30 also are expected to cause negligible, localized flow of the molten silicon in a direction that is not directed toward the removal region 26. In other words, in a manner similar to the sides of the growing ribbon crystals 32, these ridges 30 may produce substantially negligible, localized flows that are generally orthogonal to the direction of overall fluid flow. Despite this, given the low flow rate, the substantial majority of the silicon still flows in a substantially one directional manner—in this embodiment, toward the removal region 26 and generally parallel to the longitudinal axis of the crucible 14. This phenomenon may be evidenced by the increasing concentration of impurities at the removal region 26, especially when compared to the concentration of impurities in the crystal region 24 and the introduction region 22.

In other words, the stream of molten silicon across the top face of some embodiments of the crucible 14 has a substantially one directional fluid flow toward the removal region 26 despite some negligible, localized fluid turbulence. This is in contrast to some prior art systems that cause much of the molten silicon to circulate in a substantially circular or other rotational motion in or immediately proximate to the crystal region 24. Unlike those prior art systems, negligible, localized silicon flows within illustrative embodiments, as described above, should have no significant impact on performance and thus, not change the nature of the generally one directional fluid flow toward the removal region 26.

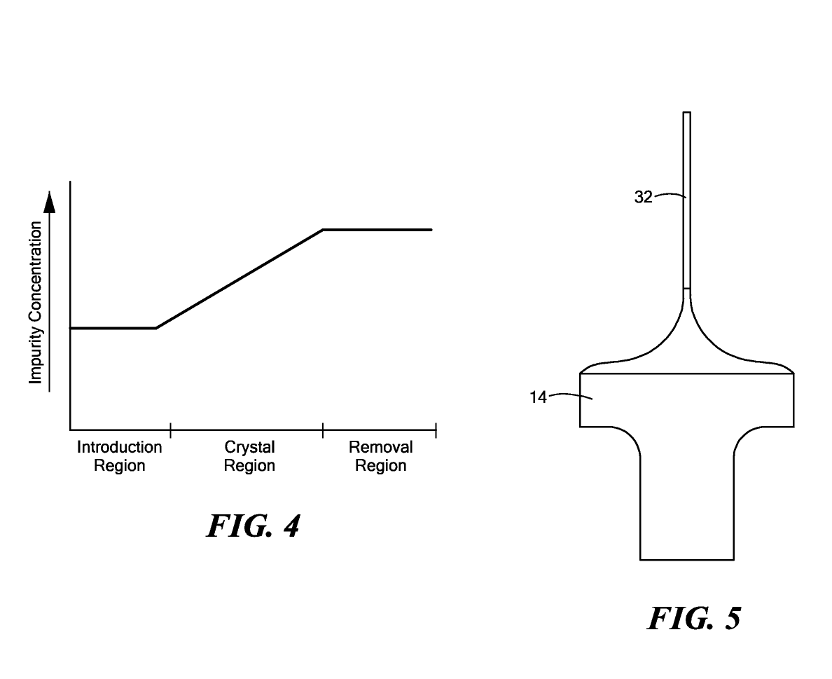

As a result of this substantially one directional flow, the concentration of impurities in the molten silicon generally increases between the introduction region 22 and the removal region 26. This increase may be higher in some regions than in others. FIG. 4 graphically shows an example of this relationship. Specifically, in the introduction region 22, the concentration of impurities is substantially constant. The impurity concentration rises in the crystal region 24 due to the above noted rejection of impurities at the crystal growth interface. This rejection also is known in the art as “segregation.” The concentration generally plateaus in the removal region 26 to a higher, substantially constant concentration. This higher concentration in the removal region 26 is expected to be greater than the average of the concentration the crystal region 24. In addition, this higher concentration also is expected to be greater than the concentration within any part of the introduction region 22.

As shown, the impurity concentration changes within the crystal region 24 only. Accordingly, the general downstream end of the crystal region 24 (from the perspective of fluid flow) has an impurity concentration that is substantially the same as that of the removal region 26. In a similar manner, the general upstream end of the crystal region 24 has an impurity concentration that is substantially the same as that of the introduction region 22. This representation, however, merely is a generalized, ideal representation of one embodiment. In practice, actual impurity concentrations can vary to some extent in all regions.

The varying impurity concentration of the crystal region 24 impacts the impurity concentration of each of the four growing ribbon crystals 32. Specifically, the ribbon crystals 32 closest to the introduction region 22 generally are expected to have fewer impurities than those closer to the removal region 26. In fact, the concentration of impurities of a single ribbon crystal 32 may vary due to this distribution. Some embodiments actually may grow a ribbon crystal 32 through the removal region 26 to remove many of the impurities. Such embodiments may or may not use the removal port 34.

The crucible 14 may contain the molten silicon in any of a number of different ways. In illustrative embodiments, the top surface of the crucible 14 is substantially planar with no sidewalls 31 (e.g., FIG. 3A). Accordingly, surface tension of the molten silicon essentially causes the crucible 14 to contain the silicon. FIG. 5 illustrates this by showing a cross-sectional view of the crucible 14 along the width of the crucible 14. This drawing also shows the side of a growing ribbon crystal 32. It should be noted that in a manner similar to other figures, FIG. 5 is schematic and thus, its dimensions are not drawn to scale.

Other embodiments of the crucible 14, however, may have perimeter walls 31 of varying heights (e.g., see FIG. 3B). Accordingly, discussion of a substantially planar or flat crucible 14, or one with walls 31, is for illustrative purposes only and thus, not intended to limit a number of other embodiments of the invention.

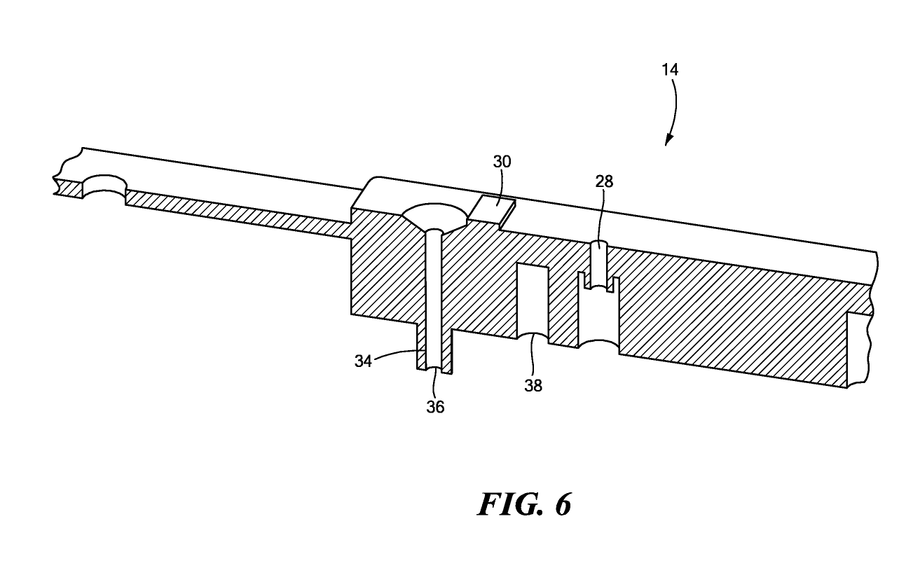

To illustrate various details of illustrative embodiments, FIG. 6 schematically shows a cross-sectional view of a portion of the length of the crucible 14 of FIG. 3A from the removal region 26 to a point just past a first string hole 28. In this embodiment, the crucible 14 has a removal port 34 with a relatively large inner dimension in the plane of the top surface of the crucible 14. This inner dimension, however, converges in a generally frustoconical shape to a passageway with a very small inner dimension. This shape effectively acts as a funnel for removing the molten silicon to be dumped.

The bottom of the removal port 34 illustratively has a capillary retention feature 36 that causes the surface tension of molten silicon to balance gravity. As discussed in greater detail below, molten silicon may be forced from the removal port 34 using a vacuum, differential pressure, or some other means. In some embodiments, however, depending on orifice size, flow, and other features, the molten silicon may exit the port 34 without assistance. Alternatively, the inner dimension of the removal port 34 may be large enough to enable gravity to remove the molten silicon also without assistance (e.g., without a vacuum). For example, in a gravity removal system, the molten silicon may form a droplet that separates from the removal port 34 after it reaches a critical size/mass. The size of this droplet may be controlled based on the type of material used in the melt and the size of the removal port 34.

FIG. 6 shows a number of other features of the crucible 14 in greater detail, such as the ridge 30 protruding slightly above the surface of the crucible 14, and the noted string hole 28. In a manner similar to the removal port 34, the string hole 28 has an inner dimension also provides similar capillary retention features 36, thus acting as an effective seal. In addition, the crucible 14 shown in FIG. 6 also has a plug hole 38 that assists in controlling the temperature of the crucible 14. To that end, insulation may be added and/or removed from the plug hole 38 depending upon the desired temperature.

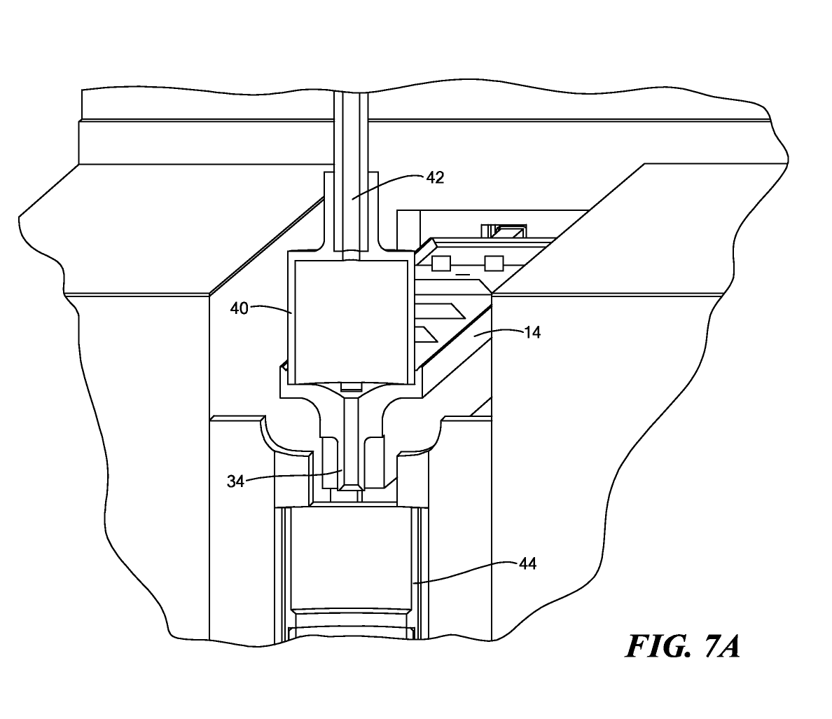

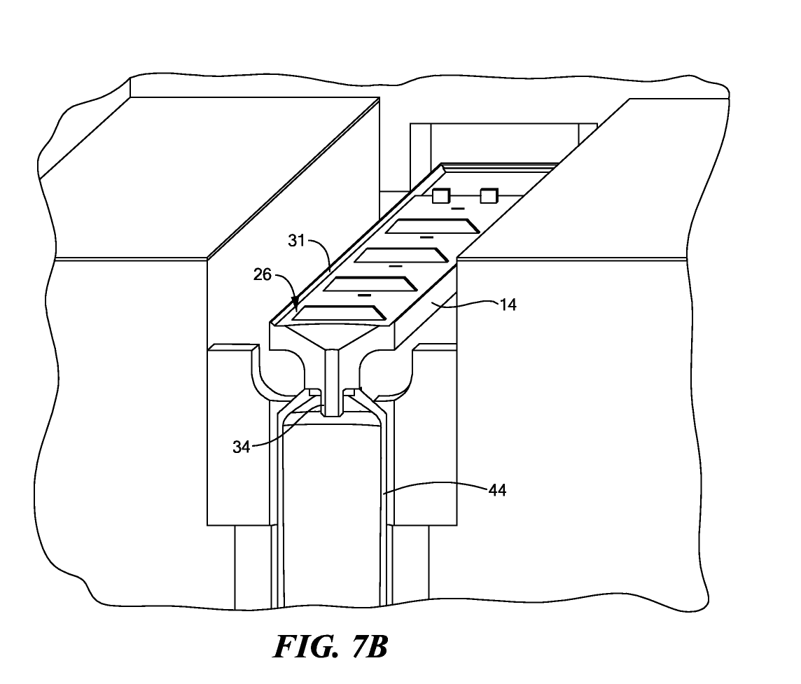

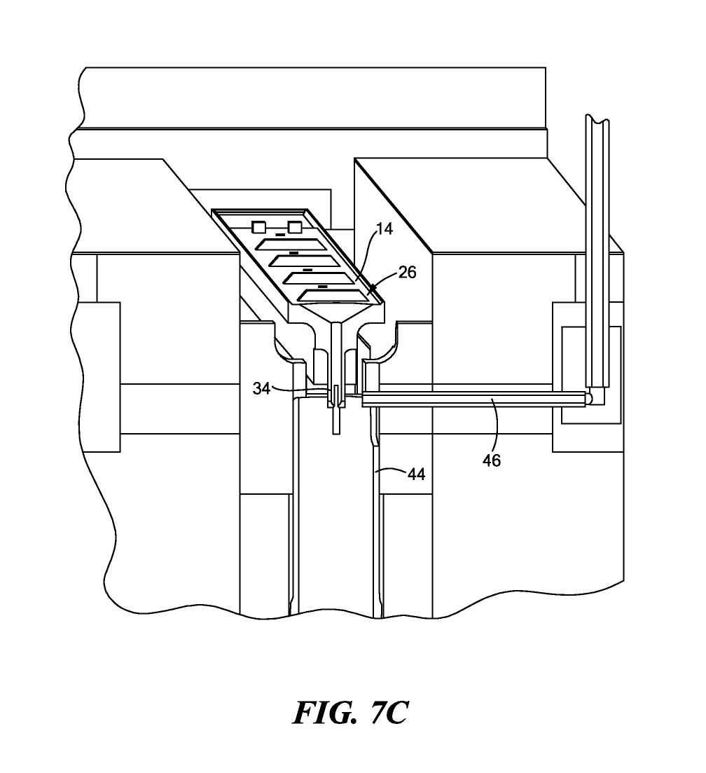

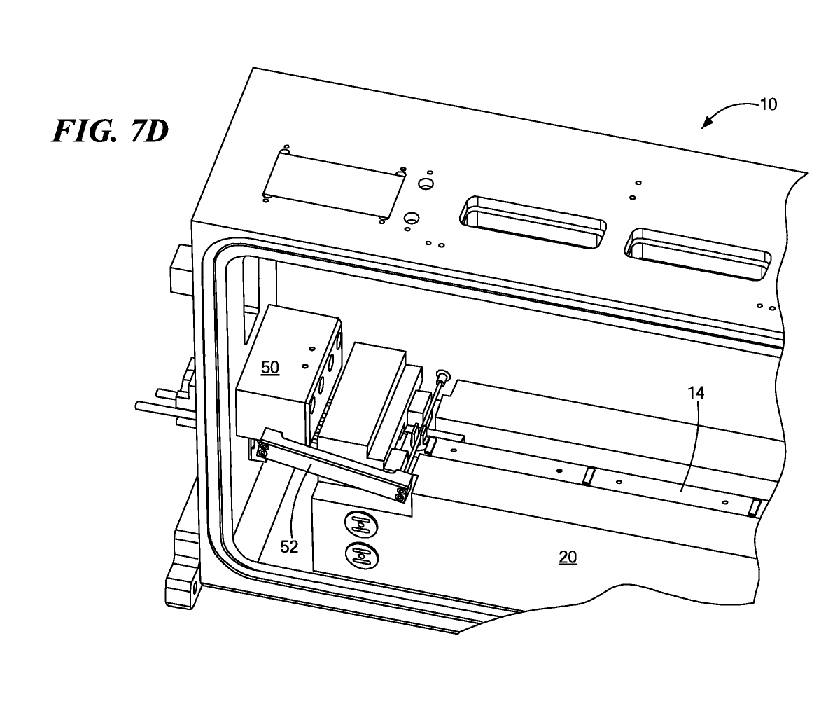

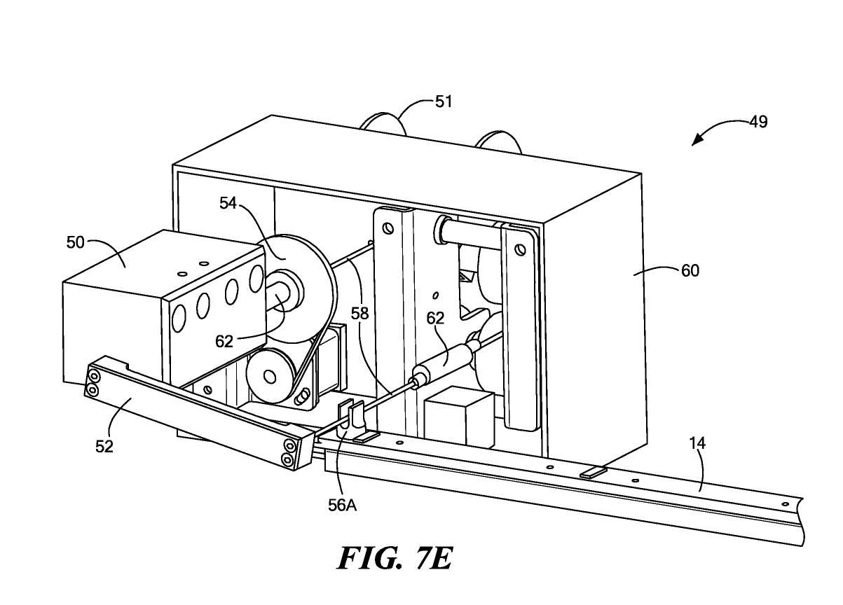

Illustrative embodiments can use a number of different techniques for removing molten silicon from the removal region 26. One such technique, described above, involves growing a sacrificial ribbon crystal 32 through the removal region 26. FIG. 7A through 7E schematically show various other techniques that may be used for removing high impurity molten silicon from the removal region 26. Each of these techniques may be used alone or in combination with other techniques. It should be noted that discussion of these techniques is not intended to imply that no other techniques can be used remove the molten silicon. Indeed, various embodiments of the invention may employ other techniques for removing silicon from the removal region 26.

FIG. 7A schematically shows an apparatus that provides a small positive pressure to the top of the removal port 34 for removing molten silicon from the removal region 26. To that end, the apparatus has a collar 40 having an open end positioned over the top of the removal port 34, and a sealed opposite end. The sealed end has a pipe 42 for receiving pressurized gas, such as argon gas, for delivering the positive pressure to the removal port 34. This apparatus may be movable or stationary.

The system also has a removable receptacle 44 coupled about the bottom of the removal port 34 for receiving removed/dumped molten silicon. This receptacle 44 may be positioned within the housing 12, exterior to the housing 12, or partially within the housing 12. In illustrative embodiments, the receptacle 44 is water cooled and exterior to the housing 12.

Accordingly, application of a positive pressure toward the top portion of the removal port 34 produces a pressure differential that forces molten silicon droplets from the removal port 34 to the receptacle 44. The size of each droplet is controlled by the inner dimension of the removal port, and the density and surface tension of the molten silicon. For example, a removal port 34 having a substantially round inner dimension of 4 millimeters may produce a droplet with a mass of about 0.9 grams.

Rather than, or in addition to, positive pressure, some embodiments apply a small vacuum (e.g., about 800 Pa below atmospheric pressure) from the bottom of the removal port 34 (i.e., a negative pressure). To that end, FIG. 7B schematically shows a receptacle 44 that applies a vacuum to the outlet portion of the removal port 34. The receptacle 44 of this embodiment may be similar to that discussed above with regard to FIG. 7A, but with an additional vacuum connection (not shown). In some embodiments, including others discussed herein, a laser or photosensor can be positioned outside the furnace 10 to determine when the droplet has detached. This enables control of the vacuum level and gradual withdrawal of the droplets. For example, one drop of the melt may be extracted by ramp up to about 6 iwc (inches of water column) vacuum in about 800 ms, down to about 0 in 200 ms. Testing has demonstrated that twelve single controlled drops can be extracted using an automatic timed program.

FIG. 7C schematically shows another embodiment that does not require capillary retention. Instead, this embodiment selectively freezes (i.e., solidifies) and unfreezes drops of molten silicon to meter fluid flow through the removal port 34. To that end, this embodiment has a tube 46 for delivering a gas jet that cools the removal port 34. For example, the gas jet may selectively deliver argon gas to the removal port 34. This embodiment also may have a receptacle 44 for receiving the discarded silicon. This receptacle 44 may be similar to those discussed above with regard to FIGS. 7A and 7B.

FIGS. 7D and 7E schematically show yet another technique for removing impurities from the removal region 26. Unlike the methods discussed above, this technique does not require a removal port 34. Instead, this embodiment uses a wick 48 for removing impurities within the silicon. To that end, this embodiment has a wick assembly 49 that passes a wick 48 through the molten silicon in the crucible 14. FIG. 7D schematically shows a cut away view of the furnace 10 with the wick assembly 49, while FIG. 7E schematically shows a close up of the wick assembly 49 within the housing 12.

In this embodiment, the wick 48 may be formed from a material similar to that of the string used to form the ribbon crystals 32. Specifically, the wick 48 may be wound on a spool 51 from which it is removed and guided toward the crucible 14. A motor 50, such as a DC electric stepper motor, pulls the wick 48 from the spool 51 to a pivotable arm 52 that redirects the wick 48 toward the crucible 14. A second motor 54 or similar pivoting apparatus controls the pivotal motion on the arm 52. The wick 48 traverses through the crucible 14 by means of a guide member 56A extending upwardly from the removal region 26 of the crucible 14.

Silicon freezes/adheres to the outer surface of the wick 48 after it passes through the molten silicon. Specifically, to remove impurities from the molten silicon, the wick 48 can either pass across the surface of the molten silicon, or through a deeper portion of the molten silicon. A pair of motorized rollers 58 forces the silicon covered wick 48 toward an external location where it can be discarded.

In illustrative embodiments, the wick assembly 49 has a wicking housing 60 that normally is exterior to the main housing 12. This wicking housing 60 contains various portions of the wick assembly 49, such as the rollers 58, the second motor 54, and another guide member (not shown) to guide the wick 48 from the spool 51 (partially shown). In a manner similar to the interior of the main housing 12, this housing 60 also may be substantially oxygen free and filled with some alternative gas, such as argon. Seals 62 may provide a sealed interface for the wick 48 between the two housings 12 and 60.

In alternative embodiments, the wick 48 takes on a form other than a string. For example, the wick 48 may be a tube, a ribbon crystal, a wetted piece of string or a porous or wetting material. Alternative embodiments may cause the wick 48 to contact the molten silicon in the same manner, or in a different manner than that shown in FIGS. 7D and 7E.

As noted above, other techniques can be utilized to remove the molten silicon from the crucible 14. For example, the silicon may be urged from the crucible 14 by means of a temperature fluctuation. Accordingly, discussion of the various silicon removal techniques is for discussion of those specific embodiments.

After set up, the system essentially produces silicon ribbon crystals 32 in a substantially continuous manner. FIG. 8 shows a simplified process of forming silicon ribbon crystals 32 in accordance with illustrative embodiments of the invention. Each of the steps in this process may be executed sequentially, substantially simultaneously, and/or a different order at different times. It thus should be noted that FIG. 8, which shows each step as being executed in parallel, is but one embodiment.

Specifically, step 800 periodically adds silicon feedstock to the crucible 14 via the feed inlet 18 in the furnace housing 12. As noted above, this silicon feedstock may have a higher impurity concentration than others. Despite that, illustrative embodiments permit use of such feedstock to produce lower impurity concentration silicon ribbon crystals 32. Illustrative embodiments may translationally move the silicon feedstock to the feed inlet 18 by any conventional means, such as with a moving belt. This silicon feedstock may be added to the feed inlet 18 in any conventional form, such as in the form of granules, pellets, or simply crushed material. In other embodiments, the silicon feedstock is added to the feed inlet 18 in liquid form.

Step 802 simply forms single crystal or multi-crystalline silicon ribbon crystals 32 in a conventional manner by passing the string through the string holes 28 in the crucible 14. Step 804 periodically removes molten silicon from the removal region 26 in a manner such as that described above. In alternative embodiments, rather than removing molten silicon from the removal region 26, the system removes solid silicon from the removal region 26. It should be noted that although the addition and dumping of silicon is referred to as being “periodic,” such steps may be done at regular intervals, or intermittently on an “as needed” basis.

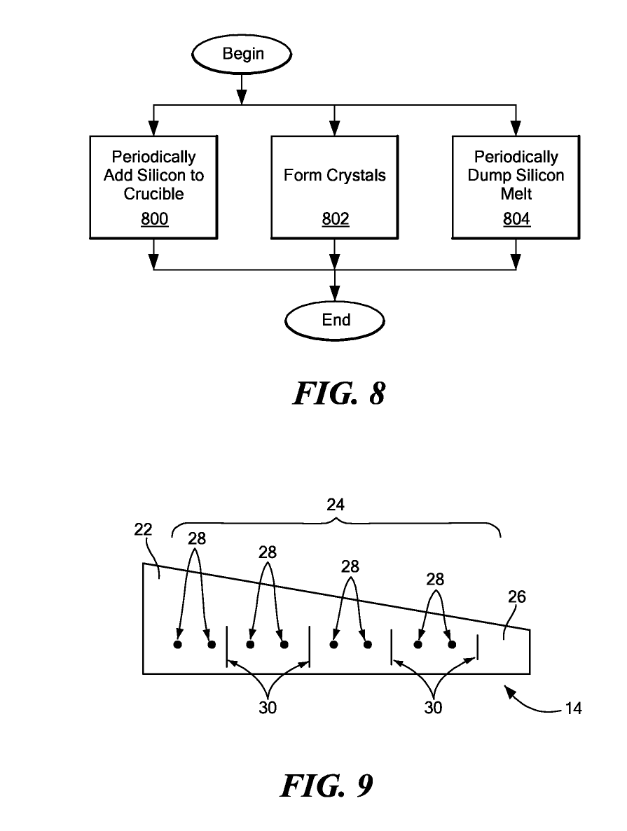

Embodiments discussed above describe the crucible 14 as having a substantially rectangular, elongated shape. In alternative embodiments, the crucible 14 may take on some other shape that is not rectangular, not elongated, or neither rectangular nor elongated. FIG. 9 schematically shows one such embodiment, in which the crucible 14 has a relatively wide introduction region 22, but converges to a narrowing end portion that contains the removal region 26. This embodiment of the crucible 14 has a number of similar features to that of the crucible 14 discussed above, such as string holes 28, four crystal sub-regions, and flow control ridges 30. Due to its shape and anticipated flow rates, the flow of substantial majority of the molten silicon should converge generally toward the removal region 26.

The shape and configuration of the crucible 14 shown in FIG. 9 is but one of a wide variety of shapes and may be used. Other irregularly shaped or regularly shaped crucibles 14 may be used. In such cases, the geometry and shape of the crucible 14, coupled with other considerations, such as the anticipated flow rate of the molten silicon, promote the generally one directional flow toward the removal region 26.

In some other embodiments of the invention, the crucible 14 may be elongated but curved. In that case, the molten silicon may be considered as flowing in a substantially one directional manner if the substantial majority of it follows the outer boundary of such crucible 14. Accordingly, although the silicon may move in an arc-like manner, for example, such material flow still is considered to be substantially one directional if the substantial majority of it generally follows the direction of the curve and contour of the crucible 14.

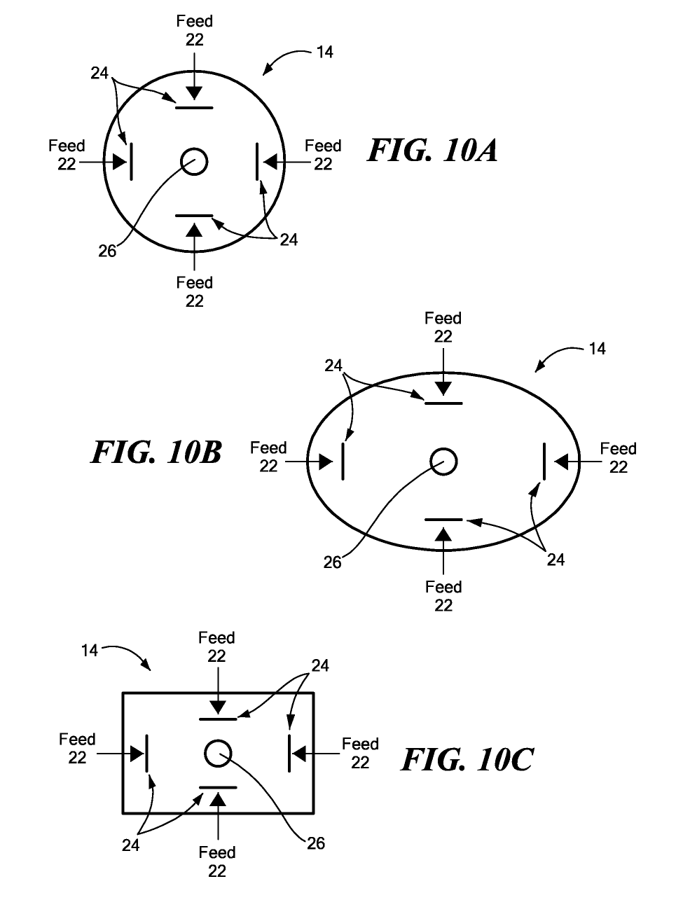

FIGS. 10A to 10C schematically show various embodiments of a type of crucible 14 having the removal region 26 substantially at its center. Specifically, in the embodiments shown in these figures, the furnace 10 is configured to provide one or more areas for adding silicon feedstock to the crucible 14. With regard to FIG. 10A, for example, which shows a substantially round crucible 14, using clock time positions as a reference, the silicon feedstock is added at the 12 o'clock, three o'clock, six o'clock, and nine o'clock positions (or some similarly spaced areas). The introduction region 22 therefore is considered to be a toroidally shaped region (i.e., shaped like a donut) with four feed inlet areas circumscribing of the top face of the crucible 14. The inner diameter of introduction region 22 clearly is much larger than that of the removal region 26. In a manner similar to the introduction region 22, the crystal region 24 also is a toroidally shaped region of the crucible 14 radially between the introduction region 22 and the removal region 26. The inner diameter of the crystal region 24 thus is smaller than the inner diameter of the introduction region 22. In a manner similar to the embodiment of the crucible 14 shown in FIG. 3A, these embodiments of the crucible 14 thus position the crystal region 24 radially between the introduction region 22 and the removal region 26. As such, for the same reasons as discussed above with regard to the crucible 14 of FIG. 3A, this embodiment of the crucible 14 also is configured to cause the substantial majority of material to flow generally directly from the introduction region 22 toward the removal region 26. In these embodiments, the substantial majority of the molten silicon flow converges toward the removal region 26; i.e., in this case, toward the general center of the crucible 14. Such embodiments do not provide a generally one directional flow. Accordingly, this fluid flow should cause a portion of the impurities to move with the silicon flow to the removal region 26. This favorably should cause an increased concentration of impurities in the removal region 26.

Also in a manner similar to the crucible 14 shown in FIG. 3A, this embodiment should not cause the molten silicon to flow in a circular manner. Instead, the molten silicon substantially linearly flows radially inwardly from an outer diameter of the crucible 14 toward the removal region 26.

As noted above, the shapes of the crucibles 14 in this embodiment may vary. For example, FIG. 10A shows a circularly shaped crucible 14, while FIG. 10B shows an elliptically shaped crucible 14. As yet another example, FIG. 10C shows a rectangularly shaped crucible 14. Of course, the crucible 14 of this embodiment may take on other shapes that are not shown, such as an octagonal shape or some irregular shape. If the shape of the crucible 14 of this embodiment is not symmetrical, then the removal region 26 may be in some generally central location.

Silicon crystals produced by illustrative embodiments may serve as the basis for a wide variety of semiconductor products. For example, among other things, the ribbon crystals 32 may be diced into wafers that form highly efficient solar cells.

Accordingly, various embodiments effectively flush many impurities from the crystal region 24 of the crucible 14. This flushing causes impurities to accumulate at relatively high concentrations in the removal region 26 compared to 1) the impurity concentration of the introduction region 22 and 2) the average impurity concentration of the crystal region 24. Various embodiments of the invention thus facilitate production of high quality crystals (i.e., having lower impurity concentrations) from less-expensive, higher impurity material feedstock. Consequently, various high efficiency semiconductor devices may be produced at a lower cost.

Although the above discussion discloses various exemplary embodiments of the invention, it should be apparent that those skilled in the art can make various modifications that will achieve some of the advantages of the invention without departing from the true scope of the invention.

What is claimed is:

1. A system for producing a crystal formed from a material having impurities, the system comprising:
a crucible for containing the material and having a crystal region for forming the crystal, an introduction region for receiving the material, and a removal region for removing a portion of the material,
the crucible being configured to produce a generally one directional flow of the material in liquid form from the introduction region toward the removal region,
the generally one directional flow causing the removal region to have a higher concentration of impurities than the introduction region.

2. The system as defined by claim 1 wherein the crucible has an elongated shape with a length dimension, the crystal region being positioned between the introduction region and the removal region along the long dimension.

3. The system as defined by claim 2 wherein the crucible has a width dimension, the length dimension being at least three times greater than the width dimension.

4. The system as defined by claim 1 wherein the crucible has a length dimension and a width dimension, the crucible being configured to direct the flow of the material generally in one direction toward the removal region in the length direction.

5. The system as defined by claim 1 further comprising a wick traversing the removal region.

6. The system as defined by claim 1 wherein the crucible is configured to cause the material to have a generally increasing amount of impurities in the material from the introduction region toward the removal region.

7. The system as defined by claim 1 wherein the crucible is shaped to have a narrowing end portion, at least a portion of the removal region being within the narrowing end portion.

8. The system as defined by claim 1 wherein the material is silicon.

9. The system as defined by claim 1 wherein the crystal is a silicon ribbon crystal.

10. The system as defined by claim 1 wherein the crucible is configured to cause substantially no rotational flow of the material in or immediately proximate to the crystal region.

11. The system as defined by claim 1 wherein the crystal region includes a plurality of crystal sub-regions for growing a plurality of crystals.

12. The system as defined by claim 1 wherein the crucible is substantially planar and contains the material by surface tension.

13. The system as defined by claim 1 further comprising the material in liquid form, the material being contained by the crucible.

14. The system as defined by claim 1 wherein the removal region has a removal port for removing a portion of the material, the removal port being spaced from the crystal region.

15. The system as defined by claim 14 further comprising a pressure source for urging material through the removal port.

16. The system as defined by claim 14 further comprising a container coupled to the removal port, the container receiving material removed via the port.

17. The system as defined by claim 1 wherein the generally one directional flow causes the removal region to have a higher concentration of impurities than the average of the crystal region.

18. A method of forming a crystal, the method comprising:
adding material to an introduction region of a crucible, the crucible also having a crystal region for producing the crystal, the crucible further having a removal region;
causing the material to flow in a substantially one directional manner in the direction of the removal region, at least some of the impurities flowing with the one directional flow to the removal region; and
removing a portion of the material from the removal region.

19. The method as defined by claim 18 wherein the crystal region has a first impurity concentration, the removal region having a second impurity concentration, the second impurity concentration being greater than the first impurity concentration.

20. The method as defined by claim 18 wherein the material comprises silicon and the crystal is a silicon ribbon crystal.

21. The method as defined by claim 18 wherein the one directional flow has substantially no rotational flow in or immediately proximate to the crystal region.

22. The method as defined by claim 18 wherein removal of at least a portion of the material at least in part causes the material to flow in a substantially one directional manner in the direction of the removal region.

23. The method as defined by claim 18 wherein causing comprises at least using surface tension to contain the material.

24. The method as defined by claim 18 wherein the crystal region is between the introduction region and the removal region.

25. The method as defined by claim 18 wherein causing comprises causing the material to flow in a substantially one directional manner in a linear direction toward the removal region.

26. A ribbon pulling system for producing a ribbon crystal formed from silicon having impurities, the system comprising:
a crucible for containing liquid silicon and having a crystal region for forming the crystal, an introduction region for receiving silicon, and a removal region for removing a portion of the silicon in liquid form,
the crucible being configured to produce a generally one directional flow of the silicon in liquid form from the introduction region toward the removal region,
the generally one directional flow causing the removal region to have a higher concentration of impurities than the introduction region.

27. The system as defined by claim 26 wherein the crucible has an elongated shape with a length dimension, the crystal region being positioned between the introduction region and the removal region along the long dimension.

28. The ribbon pulling system as defined by claim 26 wherein the crystal region has a plurality of string hole pairs.

29. The ribbon pulling system as defined by claim 26 wherein the crucible is substantially planar and contains the silicon by surface tension.

30. The ribbon pulling system as defined by claim 26 wherein the crystal region comprises a plurality of crystal sub-regions for growing a plurality of crystals.

31. A system for producing a ribbon crystal formed from a material having impurities, the system comprising:
a crucible for containing the material and having a crystal region for forming the crystal, an introduction region for receiving the material, and a removal region for removing a portion of the material,
the crucible being configured to cause substantially all material to flow generally directly from the introduction region toward the removal region,
the flow causing the removal region to have a higher concentration of impurities than the introduction region.

32. The system as defined by claim 31 wherein the removal region is positioned at the general center of the crucible, the flow of material being directed toward the general center of the crucible.

33. The system as defined by claim 31 wherein the crucible has a generally rectangular shape.

34. The system as defined by claim 31 wherein the crucible has a generally circular shape or elliptical shape.

35. The system as defined by claim 31 wherein the crucible has an outside circumscribing edge, the introduction region being closer to the circumscribing edge than the removal region.

36. The system as defined by claim 35 wherein the crystal region is between the introduction region and the removal region.

37. The system as defined by claim 31 wherein the crucible has an elongated shape, the crucible being configured to produce a generally one directional flow of the material in liquid form from the introduction region toward the removal region.

38. The system as defined by claim 31 wherein the crucible is configured to cause the substantial majority of the material to converge toward the removal region.

39. The system as defined by claim 31 wherein the crucible is configured to cause substantially no rotational flow of the material in or immediately proximate to the crystal region.

40. The system as defined by claim 31 wherein the introduction region comprises a plurality of introduction regions, the crystal region comprising a plurality of crystal regions, each introduction region having an associated crystal region.
